(19) United States
(12) Patent Application Publication
(10) Pub. No.: US 2016/0268316 A1
(43) Pub. Date: Sep. 15, 2016

(54) ARRAY SUBSTRATE AND MANUFACTURING METHOD THEREOF, AND DISPLAY DEVICE

(71) Applicant: BOE TECHNOLOGY GROUP CO., LTD., Beijing (CN)

(72) Inventors: Heecheol KIM, Beijing (CN); Hyun Sic CHOI, Beijing (CN)

(73) Assignee: BOE TECHNOLOGY GROUP CO., LTD., Beijing (CN)

(21) Appl. No.: 14/769,931

(22) PCT Filed: Dec. 1, 2014
(86) PCT No.: PCT/CN2014/092699

§ 371 Date: Aug. 24, 2015

(30) Foreign Application Priority Data
Aug. 15, 2014 (CN) 201410401878.6

(51) Int. Cl. H01L 27/12

(52) U.S. Cl. CPC H01L 27/1248; H01L 27/1262

(57) ABSTRACT

An array substrate and a manufacturing method thereof, and a display device are provided. The array substrate includes: a base substrate (1), a gate line (2), a data line (3), and a thin film transistor (10), which are formed on the base substrate (1); a first planarization layer (5), formed on the base substrate (1), the gate line (2), the data line (11) and the thin film transistor (10), a via hole (12) being formed in the first planarization layer (5), and part of a region of the via hole (12) being corresponding to a drain electrode (4) of the thin film transistor (10); a first electrode (7), formed on the first planarization layer (5) and in the via hole (12), the first electrode being connected with the drain electrode (4); a passivation layer (8), formed on the first electrode (7); and a second electrode (9), formed on the passivation layer (8).

### TECHNICAL FIELD

Embodiments of the disclosure relate to an array substrate and a manufacturing method thereof, and a display device.

### BACKGROUND

A display device in an ADvanced Super Dimension Switch (ADS) mode has become an important mode of the display device, due to advantages such as wide viewing angle, high transmittance and high definition.

FIG. 1 is a top view of a conventional array substrate in an ADS mode; and FIG. 2 is a sectional view along A-A direction in FIG. 1. As illustrated in FIG. 1 and FIG. 2, the array substrate comprises: a base substrate, and a gate line 2, a data line 11 and a thin film transistor 10 formed on the base substrate. The gate line 2 and the data line 11 define a pixel unit, and a first planarization layer 5 is formed on the gate line 2, the data line 11 and the thin film transistor 10. A first electrode 7 is formed on the first planarization layer 5, and a first via hole 6 is formed in the first electrode 7 and the first planarization layer 5, and corresponds to a drain electrode 4 of the thin film transistor 10. Particularly, the drain electrode 4 includes a via hole pad 41, and the first via hole 6 is positioned right on the via hole pad 41. A passivation layer 8 is formed on the first electrode 7 and in the first via hole 6, a second via hole is formed in the passivation layer 8 in the first via hole 6, a second electrode 9 is formed on the passivation layer 8 and in the second via hole, and the second electrode 9 is connected with the via hold pad 41 in the drain electrode 4 of the thin film transistor. The first planarization layer is used for increasing distances between the gate line 2, the data line 11 as well as the thin film transistor 10 and the first electrode so as to reduce stray capacitances between the gate line 2, the data line 11 as well as the thin film transistor 10 and the first electrode. The passivation layer is used for insulation between the first electrode and the second electrode.

It needs to be explained that when the first via hole 6 is formed in the first electrode 7 and the first planarization layer 5 by using a patterning process, a section shape of the formed first via hole 6 is hopper-shaped, so a cross-sectional area of the first via hole 6 gradually increases from bottom to top.

In the prior art, in order to ensure that the second via hole with a certain size can be formed in the passivation layer at the bottom of the first via hole, a minimal cross-sectional area of the first via hole often needs to be set larger. Due to an increase of the minimal cross-sectional area of the first via hole, a maximal cross-sectional area of the first via hole is correspondingly increased, while in a pixel unit, a lightproof structure is correspondingly arranged in a region of the maximal cross-sectional area of the first via hole, and no pixel display is performed in the region, so along with the increase of the maximal cross-sectional area of the first via hole, an aperture ratio of the pixel unit decreases, so that it is difficult to realize a high resolution of the display device.

### SUMMARY

One embodiment of the disclosure provides an array substrate, comprising a base substrate; a gate line, a data line, and a thin film transistor, which are formed on the base substrate; a first planarization layer, formed on the base substrate, the gate line, the data line and the thin film transistor, a via hole being formed in the first planarization layer, and part of a region of the via hole being corresponding to a drain electrode of the thin film transistor; a first electrode, formed on the first planarization layer and in the via hole, the first electrode being connected with the drain electrode; a passivation layer, formed on the first electrode; and a second electrode, formed on the passivation layer.

In one example, a second planarization layer is formed in the via hole, the second planarization layer covering the first electrode in the via hole, and the passivation layer being positioned on the second planarization layer.

In one example, the second planarization layer is made of an organic resin material.

In one example, an orthogonal projection of the via hole on the base substrate partially falls into a region of the gate line.

In one example, an orthogonal projection of the drain electrode on the base substrate falls into a region of the gate line.

Another embodiment of the disclosure further provides a display device, comprising an array substrate, the array substrate adopting the above array substrate.

Still another embodiment of the disclosure further provides a manufacturing method of an array substrate, comprising: forming a gate line, a data line and a thin film transistor on a base substrate; forming a first planarization layer on the base substrate, the gate line, the data line and the thin film transistor, and forming a first via hole in the first planarization layer, part of a region of the via hole being corresponding to a drain electrode of the thin film transistor; forming a first electrode on the first planarization layer and in the via hole, the first electrode being connected with the drain electrode; forming a passivation layer on the first electrode; and forming a second electrode on the passivation layer.

In one example, before forming the passivation layer on the first electrode, the method further comprises: forming a second planarization layer in the via hole, the second planarization layer covering the first electrode in the via hole; forming the passivation layer on the first electrode includes: forming the passivation layer on the first electrode and the second planarization layer.

In one example, forming the a second planarization layer in the via hole includes: forming an organic resin material in the via hole; and performing a planarization treatment on the organic resin material to form the second planarization layer.

In one example, an orthogonal projection of the via hole on the base substrate partially falls into a region of the gate line.

In one example, an orthogonal projection of the drain electrode on the base substrate falls into a region of the gate line.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a top view of a conventional array substrate in an ADS mode;

FIG. 2 is a sectional view along A-A direction in FIG. 1;

FIG. 3 is a sectional view of an array substrate provided by Embodiment I of the disclosure;

FIG. 4a-FIG. 4e are schematic diagrams of intermediate structures of the array substrate as illustrated in FIG. 3 in a manufacturing process;

FIG. 5 is a top view of an array substrate provided by Embodiment II of the disclosure;

FIG. 6 is a sectional view along B-B direction in FIG. 5;

FIG. 7a-FIG. 7e are schematic diagrams of intermediate structures of the array substrate as illustrated in FIG. 6 in a manufacturing process.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

### Embodiment I

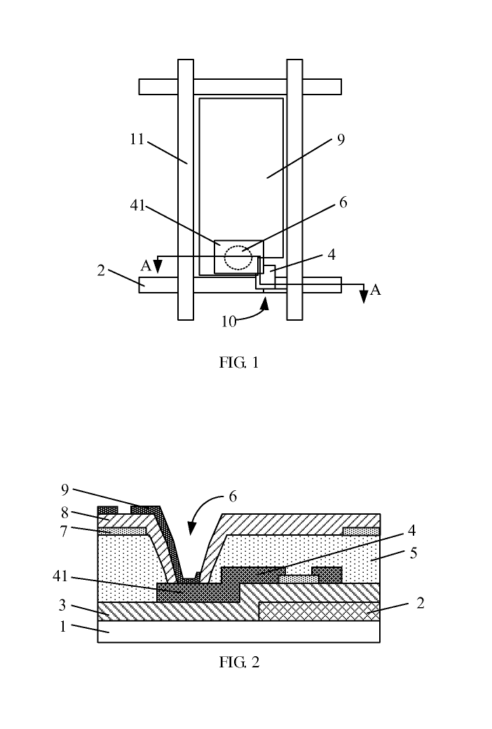

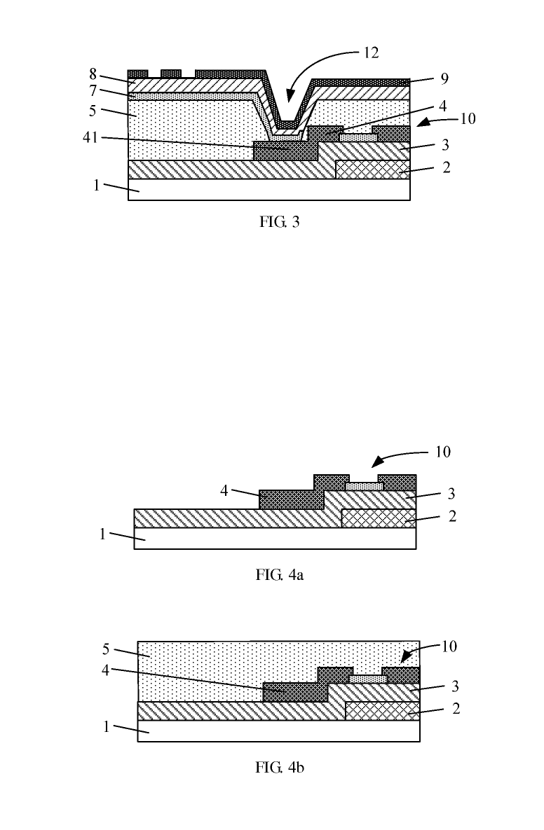

FIG. 3 is a sectional view of an array substrate provided by Embodiment I of the disclosure. As illustrated in FIG. 3, the array substrate is an array substrate in an ADS mode, the array substrate comprises: a base substrate 1, a gate line 2, a data line 11, a thin film transistor 10, a first planarization layer 5, a first electrode 7, a passivation layer 8 and a second electrode 9. The gate line 2, the data line 11 and the thin film transistor 10 are formed on the base substrate 1, and the first planarization layer 5 is formed on the gate line 2, the data line 11, the thin film transistor 10 and the base substrate 1. A via hole 12 is formed in the first planarization layer 5, part of a region of the via hole 12 corresponds to a drain electrode 4 of the thin film transistor 10, and the first electrode 7 is formed on the first planarization layer 5 and in the via hole 12, and is connected with the drain electrode 4. The passivation layer 8 is formed on the first electrode 7 and the second electrode 9 is formed on the passivation layer. It needs to be explained that a top view of FIG. 3 can refer to FIG. 1.

In the embodiment, the first electrode 7 is a pixel electrode, which is a plate electrode. The second electrode 9 is a common electrode, which is a slit electrode.

It needs to be explained that the thin film transistor includes: a gate electrode, a gate insulating layer 3, an active layer, a source electrode and a drain electrode 4. The gate electrode and the gate line 2 are arranged on a same layer, and the source electrode and the drain electrode 4 are arranged on a same layer as the data line.

In the embodiment, as a via hole needs not to be formed again in the passivation layer 8 in the via hole 12 formed in the first planarization layer 5, a minimal cross-sectional area of the via hole 12 formed on the first planarization layer 5 can be correspondingly reduced, a size of a via hole pad 41 in the drain electrode 4 is correspondingly reduced, a maximal cross-sectional area of the via hole 12 can be correspondingly reduced, and an aperture ratio of a pixel unit is increased.

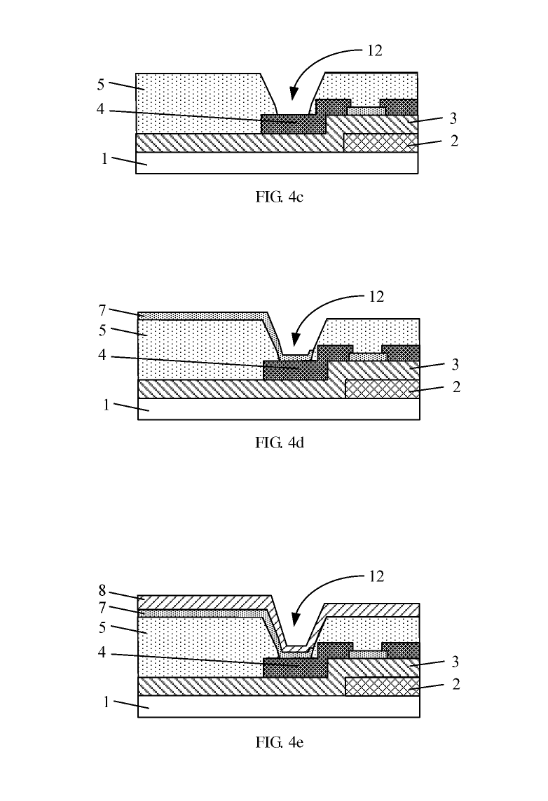

FIG. 4a-FIG. 4e are schematic diagrams of intermediate structures of the array substrate as illustrated in FIG. 3 in a manufacturing process. As illustrated in FIG. 4a-FIG. 4e, the manufacturing method comprises the following steps.

Step 101: forming a gate line, a data line and a thin film transistor on a base substrate.

With reference to FIG. 4a, the gate line 2, the data line 11 and the thin film transistor 10 are formed on the base substrate 1 by multiple patterning processes, and the process is similar to that in the prior art, and is not repeated herein.

A size of a via hole pad 41 in a drain electrode 4 of the thin film transistor 10 formed in step 101 is smaller than that of a via hole pad 41 in the prior art, and the via hole pad 41 is positioned in a pixel unit.

Step 102: forming a first planarization layer on the base substrate, the gate line, the data line and the thin film transistor, and forming a via hole in the first planarization layer, part of a region of the via hole being corresponding to a drain electrode of the thin film transistor.

With reference to FIG. 4b and FIG. 4c, a layer of organic resin material is formed on the base substrate 1, the gate line 2, the data line 11 and the thin film transistor 10, then the layer of organic resin material is subjected to planarization treatment, to form a first planarization layer 5, and then a via hole 12 is formed in the first planarization layer 5 by a patterning process, and the via hole 12 corresponds to the drain electrode 4 of the thin film transistor. Particularly, the via hole is positioned directly above the via hole pad 41 in the drain electrode.

Step 103: forming a first electrode on the first planarization layer and in the via hole, the first electrode being connected with the drain electrode.

With reference to FIG. 4d, a first electrode 7 is formed on the first planarization layer 5 and in the via hole 12 by a patterning process, wherein the first electrode 7 is made of a transparent and conductive material, such as Indium Tin Oxide (ITO).

Step 104: forming a passivation layer on the first electrode.

With reference to FIG. 4e, a passivation layer 8 is formed on the first electrode 7 by a coating process, wherein part of the passivation layer 8 is formed in the via hole 12, the passivation layer 8 can be made of SiN or SiO₂, and achieves an insulation function.

Step 105: forming a second electrode on the passivation layer.

With reference to FIG. 3, a second electrode 9 is formed on the passivation layer 8 by a patterning process, wherein the second electrode 9 is made of a transparent and conductive material, such as ITO.

Embodiment I of the disclosure provides an array substrate and a manufacturing method thereof, wherein a first electrode in the array substrate is connected with a drain electrode through a via hole, a passivation layer is formed on the first electrode, and a second electrode is formed on the passivation layer. In the embodiment of the disclosure, as a via hole needs not to be formed again in the passivation layer in the via hole formed on the first planarization layer, a minimal cross-sectional area of the via hole formed on the first planarization layer can be correspondingly reduced, a maximal cross-sectional area of the via hole can be correspondingly reduced, and an aperture ratio of a pixel unit is increased.

### Embodiment II

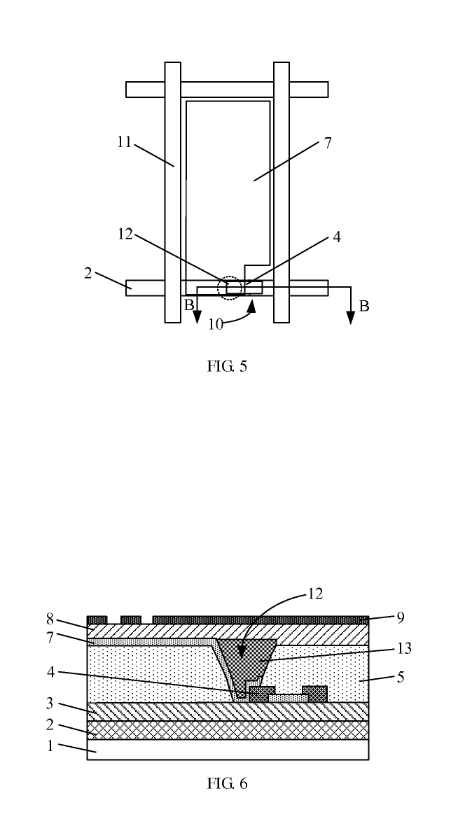

FIG. 5 is a top view of an array substrate provided by Embodiment II of the disclosure, FIG. 6 is sectional view along B-B direction in FIG. 5. As illustrated in FIG. 5 and FIG. 6, the array substrate is an array substrate in an ADS mode, the array substrate comprises: a base substrate 1, a gate line 2, a data line 11, a thin film transistor 10, a first planarization layer 5, a first electrode 7, a second planarization layer 13, a passivation layer 8 and a second electrode 9. The gate line 2, the data line 11 and the thin film transistor 10 are formed on the base substrate 1, and the first planarization layer 5 is formed on the gate line 2, the data line 11, the thin film transistor 10 and the base substrate 1. A via hole 12 is formed in the first planarization layer, part of a region of the via hole 12 corresponds to a drain electrode 4 of the thin film transistor 10, the first electrode 7 is formed on the first planarization layer 5 and in the via hole 12, and is connected with the drain electrode 4, the second planarization layer 13 is formed in the via hole 12 and covers the first electrode 7 in the via hole 12, the passivation layer 8 is formed on the first electrode 7 and on the second planarization layer 13, and the second electrode 9 is formed on the passivation layer.

For example, as illustrated in FIG. 5, an orthogonal projection of the drain electrode 4 on the base substrate falls into a region of the gate line 2.

In the embodiment, the first electrode 7 is a pixel electrode, which is a plate electrode. The second electrode 9 is a common electrode, which is a slit electrode.

The embodiment differs from the above Embodiment I in that in the array substrate provided by the embodiment, a projection of the via hole on the first planarization layer in a vertical direction (namely, the orthogonal projection on the base substrate) partially falls into a region of the gate line. In addition, the second planarization layer 13 is formed in the via hole 12, and covers the first electrode 7 in the via hole 12.

It can be known from the technical solution of the above Embodiment I that in the technical solution of the disclosure, the minimal cross-sectional area of the via hole 12 can be reduced. In the embodiment, as the minimal cross-sectional area of the via hole 12 is reduced, the position of the via hole 12 is not limited in a pixel unit any more. For example, the via hole 12 is arranged on the gate line 2, so that an area of a display region of the pixel unit can be effectively increased, and the aperture ratio of the pixel unit is enhanced. It needs to be explained that as the via hole 12 is formed over the gate line 2, the size of the drain electrode 4 in the thin film transistor 10 can be correspondingly reduced (a via hole pad is omitted), meanwhile, by adopting the manner in which the first electrode 7 is overlapped on the drain electrode 4 as illustrated in FIG. 6 (part of the first electrode 7 is positioned on a gate insulating layer 3, and another part of the first electrode 7 is positioned on the drain electrode 4), the size of the drain electrode 4 can be further reduced, namely, the whole size of the thin film transistor can be reduced. As the size of the thin film transistor is reduced, a high resolution of a display device is facilitated.

Further, in the embodiment, the second planarization layer 13 covers the first electrode 7 in the via hole 12, and the passivation layer 8 is formed on the first electrode 7 and the second planarization layer 13, so a convex-concave structure at the via hole 12 is avoided, and light leakage phenomenon at the via hole 12 can be prevented.

Optionally, the second planarization layer 13 is made of an organic resin material. The organic resin material is good in flowability, and can be gathered and filled in the via hole, which is convenient for subsequent planarization treatment.

The maximal cross-sectional area of the via hole in the array substrate provided by the disclosure is still smaller than the maximal cross-sectional area of the via hole in the array substrate provided by Embodiment I. Particularly, with reference to FIG. 3, the via hole 12 of the array substrate provided in Embodiment I is enclosed by the first planarization layer 5, the first electrode 7, the passivation layer 8 and the second electrode 9. With reference to FIG. 6, the via hole 12 in the array substrate provided by the present embodiment is only enclosed by the first planarization layer 5 and the first electrode 7, so a height of the via hole 12 in the array substrate provided by the embodiment is less than that of the via hole 12 in the array substrate provided by Embodiment I under the premise that the minimal cross-sectional areas of the two via holes 12 and inclination angles of inner walls of the via holes 12 are equal. The maximal cross-sectional area of the via hole 12 in the array substrate provided by the present embodiment is smaller than that of the via hole 12 in the array substrate provided by Embodiment I, so even if the via hole 12 in the array substrate provided by the embodiment is positioned in a pixel unit, the aperture ratio of the array substrate provided by the embodiment is greater than that of the array substrate provided by Embodiment I.

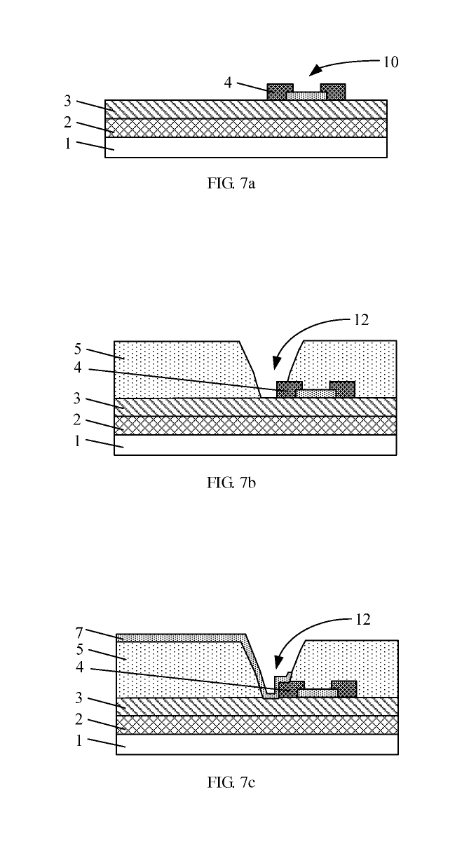

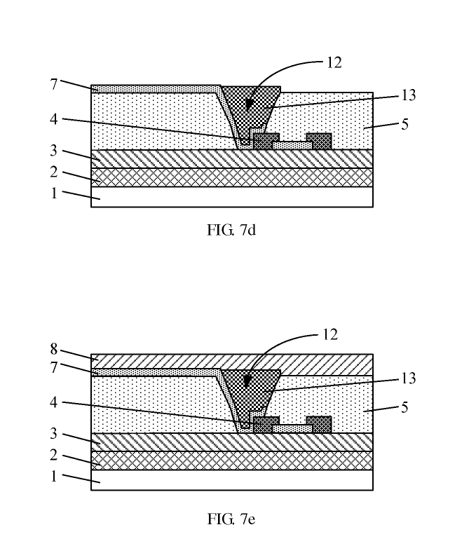

FIG. 7a-FIG. 7e are schematic diagrams of intermediate structures of the array substrate as illustrated in FIG. 6 in a manufacturing process; as illustrated in FIG. 7a-FIG. 7e, the manufacturing method comprises the following steps.

Step 201: forming a gate line, a data line and a thin film transistor on a base substrate.

With reference to FIG. 7a, step 201 is the same as step 101 in Embodiment I in process, and can refer to the content of step 101 in Embodiment I for details. But, a size of a drain electrode 4 of the thin film transistor 10 manufactured in step 201 is smaller than that of the drain electrode of the thin film transistor manufactured in step 101.

Step 202: forming a first planarization layer on the base substrate, the gate line, the data line and the thin film transistor, forming a via hole in the first planarization layer, part of a region of the via hole being corresponding to a drain electrode of the thin film transistor.

With reference to FIG. 7b, step 202 is the same as step 102 in Embodiment I in process, and can refer to the content of step 102 in Embodiment I for details. But, a projection of the via hole 12 formed in step 202 in a vertical direction falls into a region of the gate line 2, and as the size of the drain electrode 4 is smaller, part of a region on the bottom of the drain electrode 4 is connected with the gate insulating layer 3.

Step 203: forming a first electrode on the first planarization layer and in the via hole, the first electrode being connected with the drain electrode.

With reference to FIG. 7c, step 203 is the same as step 103 in Embodiment I in process, and can refer to the content of step 103 in Embodiment I for details. But, when the first electrode 7 is formed in step 203, the first electrode 7 in the via hole 12 is overlapped on the drain electrode 4, namely, part of the first electrode 7 is positioned on the gate insulating layer 3, and another part of the first electrode 7 is positioned on the drain electrode 4.

Step 204: forming a second planarization layer in the via hole, the second planarization layer covering the first electrode in the via hole.

With reference to FIG. 7d, firstly, a layer of organic resin material is formed in the via hole 12 by a coating process; due to good flowability, the organic resin material is gathered in the via hole 12; then the layer of organic resin material is subjected to planarization treatment to form the second planarization layer 13, and the second planarization layer 13 is filled in the whole via hole 12.

Step 205: forming a passivation layer on the first electrode and the second planarization layer.

With reference to FIG. 7e, the passivation layer 8 is formed on the first electrode 7 and the second planarization layer 13 by a coating process, and the passivation layer 8 can be made of SiN or SiNO₂, and achieves an insulation function.

As in step 204, the via hole 12 is filled with the second planarization layer 13, so the passivation layer 8 formed in step 205 is positioned on the via hole 12.

Step 206: forming a second electrode on the passivation layer.

With reference to FIG. 6, the second electrode 9 is formed on the passivation layer 8 by a patterning process, wherein, the second electrode is made of a transparent and conductive material, such as ITO.

Embodiment II of the disclosure provides an array substrate and a manufacturing method thereof, wherein a first electrode of the array substrate is connected with a drain electrode through a via hole, a second planarization layer is formed in the via hole, a passivation layer is formed on the first electrode and the second planarization layer, and a second electrode is formed on the passivation layer. In the embodiment of the disclosure, as it is not necessary to form the passivation layer in the via hole formed on the first planarization layer, or to form a via hole again on the passivation layer, a minimal cross-sectional area of the via hole formed on the first planarization layer can be correspondingly reduced, a maximal cross-sectional area of the via hole can be correspondingly reduced, and an aperture ratio of a pixel unit can be increased. In addition, compared with Embodiment I, the via hole in Embodiment II is arranged on the gate line, so a via hole pad structure in the drain electrode can be omitted, the size of the whole thin film transistor is reduced, and the aperture ratio of the pixel unit is further enhanced.

### Embodiment III

Embodiment III of the disclosure provides a display device; the display device comprises an array substrate, which is the array substrate provided in Embodiment I or Embodiment II, and the description in Embodiment I or Embodiment II can be referred to for details, which is not repeated herein.

The display device provided by the embodiment can be any product or part with a display function, such as a liquid crystal display device, electronic paper, a cellphone, a tablet computer, a television, a monitor, a laptop, a digital photo frame and a navigator.

Embodiment III of the disclosure provides a display device, the display device comprising an array substrate, wherein a first electrode of the array substrate is connected with a drain electrode through a via hole, a passivation layer is formed on the first electrode, and a second electrode is formed on the passivation layer. In the embodiment of the disclosure, as a via hole needs not to be formed again in the passivation layer in the via hole formed on a first planarization layer, a minimal cross-sectional area of the via hole formed on the first planarization layer can be correspondingly reduced, a maximal cross-sectional area of the via hole can be correspondingly reduced, an aperture ratio of a pixel unit is increased and a high resolution of the display device is facilitated.

The foregoing embodiments merely are exemplary embodiments of the disclosure, and not intended to define the scope of the disclosure, and the scope of the disclosure is determined by the appended claims.

The application claims priority of Chinese Patent Application No. 201410401878.6 filed on Aug. 15, 2014, the disclosure of which is incorporated herein by reference in its entirety as part of the present application.

1. An array substrate, comprising;
a base substrate;
a gate line, a data line, and a thin film transistor, which are formed on the base substrate;
a first planarization layer, formed on the base substrate, the gate line, the data line and the thin film transistor, a via hole being formed in the first planarization layer, and part of a region of the via hole being corresponding to a drain electrode of the thin film transistor;
a first electrode, formed on the first planarization layer and in the via hole, the first electrode being connected with the drain electrode;
a passivation layer, formed on the first electrode; and
a second electrode, formed on the passivation layer.

2. The array substrate according to claim 1, wherein, a second planarization layer is formed in the via hole, the second planarization layer covering the first electrode in the via hole, and the passivation layer being positioned on the second planarization layer.

3. The array substrate according to claim 2, wherein, the second planarization layer is made of an organic resin material.

4. The array substrate according to claim 1, wherein, an orthogonal projection of the via hole on the base substrate partially falls into a region of the gate line.

5. The array substrate according to claim 1, wherein, an orthogonal projection of the drain electrode on the base substrate falls into a region of the gate line.

6. A display device, comprising: the array substrate according to claim 1.

7. A manufacturing method of an array substrate, comprising:
forming a gate line, a data line and a thin film transistor on a base substrate;
forming a first planarization layer on the base substrate, the gate line, the data line and the thin film transistor, and forming a via hole in the first planarization layer, part of a region of the via hole being corresponding to a drain electrode of the thin film transistor;
forming a first electrode on the first planarization layer and in the via hole, the first electrode being connected with the drain electrode;
forming a passivation layer on the first electrode; and
forming a second electrode on the passivation layer.

8. The manufacturing method of the array substrate according to claim 7, wherein, before forming the passivation layer on the first electrode, the method further comprises:
forming a second planarization layer in the via hole, the second planarization layer covering the first electrode in the via hole;
forming the passivation layer on the first electrode includes:
forming the passivation layer on the first electrode and the second planarization layer.

9. The manufacturing method of the array substrate according to claim 8, wherein, forming the second planarization layer in the via hole includes:
forming an organic resin material in the via hole; and
performing a planarization treatment on the organic resin material to form the second planarization layer.

10. The manufacturing method of the array substrate according to claim 7, wherein, an orthogonal projection of the via hole on the base substrate partially falls into a region of the gate line.

11. The manufacturing method of the array substrate according to claim 7, wherein, an orthogonal projection of the drain electrode on the base substrate falls into a region of the gate line.

12. The array substrate according to claim 2, wherein, an orthogonal projection of the drain electrode on the base substrate falls into a region of the gate line.

13. The array substrate according to claim 3, wherein, an orthogonal projection of the drain electrode on the base substrate falls into a region of the gate line.

14. The array substrate according to claim 4, wherein, an orthogonal projection of the drain electrode on the base substrate falls into a region of the gate line.

15. The display device according to claim 6, wherein, a second planarization layer is formed in the via hole, the second planarization layer covering the first electrode in the via hole, and the passivation layer being positioned on the second planarization layer.

16. The display device according to claim 15, wherein, the second planarization layer is made of an organic resin material.

17. The display device according to claim 6, wherein, an orthogonal projection of the via hole on the base substrate partially falls into a region of the gate line.

18. The display device according to claim 6, wherein, an orthogonal projection of the drain electrode on the base substrate falls into a region of the gate line.

19. The manufacturing method of the array substrate according to claim 10, wherein, an orthogonal projection of the drain electrode on the base substrate falls into a region of the gate line.
